(19) United States
(12) Patent Application Publication
(10) Pub. No.: US 2026/0025123 A1
(43) Pub. Date: Jan. 22, 2026

(54) SURFACE ACOUSTIC WAVE FILTER INCLUDING RESONATOR WITH MULTI-STAGED REFLECTOR

(71) Applicant: Skyworks Solutions, Inc., Irvine, CA (US)

(72) Inventors: Yuya Hiramatsu, Neyagawa-Shi (JP); Tomoo Mari, Tokyo (JP)

(21) Appl. No.: 19/233,016

(22) Filed: Jun. 10, 2025

Related U.S. Application Data
(60) Provisional application No. 63/660,253, filed on Jun. 14, 2024.

(51) Int. Cl. H03H 9/25; H03H 9/145; H03H 9/64

(52) U.S. Cl. CPC H03H 9/25; H03H 9/14576; H03H 9/6483

(57) ABSTRACT

Aspects and embodiments disclosed herein include a die comprising a plurality of surface acoustic wave resonators. At least one of the plurality of surface acoustic wave resonators has an aperture that at least partially overlaps an aperture of at least one other of the plurality of surface acoustic wave resonators. The at least one of the plurality of surface acoustic wave resonators includes interdigital transducer electrodes with interdigital transducer electrode fingers having a first average pitch and reflector electrodes with reflector electrode fingers having at least two different pitches. Each of the at least two different pitches are greater than the first average pitch.

### CROSS-REFERENCE TO RELATED APPLICATIONS

This application claims priority under 35 U.S.C. § 119 (e) to U.S. Provisional Patent Application Ser. No. 63/660,253 titled “SURFACE ACOUSTIC WAVE FILTER INCLUDING RESONATOR WITH MULTI-STAGED REFLECTOR,” filed Jun. 14, 2024, the entire content of which is incorporated herein by reference for all purposes.

### BACKGROUND

### Technical Field

Embodiments of this disclosure relate to acoustic wave devices and filters including same.

### Description of Related Technology

Acoustic wave devices, for example, surface acoustic wave (SAW) and bulk acoustic wave (BAW) devices may be utilized as components of filters in radio frequency electronic systems. For instance, filters in a radio frequency front-end of a mobile phone can include acoustic wave filters. Two acoustic wave filters can be arranged as a duplexer.

### SUMMARY

In accordance with one aspect, there is provided a die comprising a plurality of surface acoustic wave resonators, at least one of the plurality of surface acoustic wave resonators having an aperture that at least partially overlaps an aperture of at least one other of the plurality of surface acoustic wave resonators, the at least one of the plurality of surface acoustic wave resonators including interdigital transducer electrodes with interdigital transducer electrode fingers having a first average pitch and reflector electrodes with reflector electrode fingers having at least two different pitches, each of the at least two different pitches being greater than the first average pitch.

In some embodiments, the interdigital transducer electrode fingers of the at least one of the plurality of surface acoustic wave resonators have a first constant pitch throughout a center portion of the interdigital transducer electrodes and a second average pitch proximate outer sides of the interdigital transducer electrodes on opposite sides of the center portion.

In some embodiments, the pitches of the interdigital transducer electrode fingers decrease monotonically with distance from outer edges of the center portion to the outer sides of the interdigital transducer electrodes.

In some embodiments, the reflector electrode fingers have a second constant pitch throughout inner portions of the reflector electrodes and a third constant pitch throughout outer portions of the reflector electrodes.

In some embodiments, the third constant pitch is greater than the second constant pitch.

In some embodiments, the second constant pitch is about 1.05 times the first constant pitch.

In some embodiments, the third constant pitch is about 1.1 times the first constant pitch.

In some embodiments, the pitches of the reflector electrode fingers increase with distance from inner sides of the reflector electrodes to outer sides of the reflector electrodes. In some embodiments, the pitches of the reflector electrode fingers increase monotonically with distance from the inner sides of the reflector electrodes to the outer sides of the reflector electrodes.

In some embodiments, the pitch of the reflector electrode fingers is about 1.05 times the first constant pitch at the inner sides of the reflector electrodes.

In some embodiments, the pitch of the reflector electrode fingers is about 1.1 times the first constant pitch at the outer sides of the reflector electrodes.

In some embodiments, each of the plurality of surface acoustic wave resonators include interdigital transducer electrodes with interdigital transducer electrode fingers having a first average pitch and reflector electrodes with reflector electrode fingers having at least two different pitches, each of the at least two different pitches being greater than the first average pitch.

In some embodiments, the die further comprises a multilayer piezoelectric substrate upon which the plurality of surface acoustic wave resonators are disposed.

In some embodiments, the at least one of the plurality of surface acoustic wave resonators and the at least one other of the plurality of surface acoustic wave resonators have partially overlapping apertures.

In some embodiments, the at least one of the plurality of surface acoustic wave resonators and the at least one other of the plurality of surface acoustic wave resonators have interdigital transducer electrode fingers with different average pitches.

In some embodiments, the at least one of the plurality of surface acoustic wave resonators and the at least one other of the plurality of surface acoustic wave resonators have reflector electrode fingers with different average pitches.

In some embodiments, the plurality of surface acoustic wave resonators form a radio frequency filter.

In some embodiments, the plurality of surface acoustic wave resonators form a radio frequency ladder filter.

In some embodiments, the radio frequency filter is included in an electronics module. In some embodiments, the electronics module is included in an electronic device. In accordance with another aspect, there is provided a radio frequency filter comprising a plurality of surface acoustic wave resonators disposed on a substrate, at least one of the plurality of surface acoustic wave resonators having an aperture that at least partially overlaps an aperture of at least one other of the plurality of surface acoustic wave resonators, the at least one of the plurality of surface acoustic wave resonators including interdigital transducer electrodes with interdigital transducer electrode fingers having a first average pitch and reflector electrodes with reflector electrode fingers having at least two different pitches, each of the at least two different pitches being greater than the first average pitch.

In some embodiments, the substrate is a multilayer piezoelectric substrate.

In some embodiments, the radio frequency filter is included in an electronic device.

### BRIEF DESCRIPTION OF THE DRAWINGS

Embodiments of this disclosure will now be described, by way of non-limiting example, with reference to the accompanying drawings.

FIG. 1A is a simplified plan view of an example of a surface acoustic wave resonator;

FIG. 1B is a simplified plan view of another example of a surface acoustic wave resonator;

FIG. 1C is a simplified plan view of another example of a surface acoustic wave resonator;

FIG. 2 is a cross-sectional view of a portion of an example of a surface acoustic wave resonator;

FIG. 3 is a cross-sectional view of a portion of an example of a temperature compensated surface acoustic wave resonator;

FIG. 4 is a schematic diagram of a radio frequency ladder filter;

FIG. 5 a simplified plan view of another example of a surface acoustic wave resonator;

FIG. 6 illustrates an example of a layout of resonators forming a portion of a SAW filter;

FIG. 7 illustrates results of a simulation of filter insertion loss and resonator conductance for a SAW filter formed from resonators as illustrated in FIG. 5;

FIG. 8A a simplified plan view of another example of a surface acoustic wave resonator;

FIG. 8B illustrates a comparison between interdigital transducer electrode finger and reflector electrode finger pitches of examples of two resonators having at least partially overlapping apertures;

FIG. 9A a simplified plan view of another example of a surface acoustic wave resonator;

FIG. 9B illustrates a comparison between interdigital transducer electrode finger and reflector electrode finger pitches of examples of two resonators having at least partially overlapping apertures;

FIG. 10 illustrates results of a simulation of filter insertion loss and resonator conductance for a SAW filter formed from resonators as illustrated in FIG. 8A;

FIG. 11 is a block diagram of one example of a filter module that can include one or more surface acoustic wave resonators according to aspects of the present disclosure;

FIG. 12 is a block diagram of one example of a front-end module that can include one or more filter modules according to aspects of the present disclosure; and

FIG. 13 is a block diagram of one example of a wireless device including the front-end module of FIG. 12.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

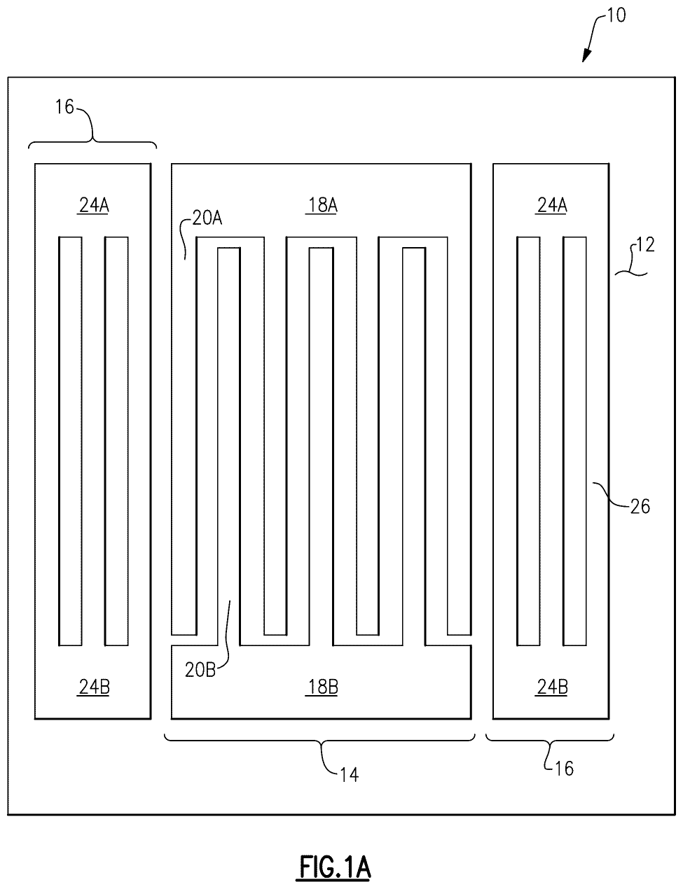

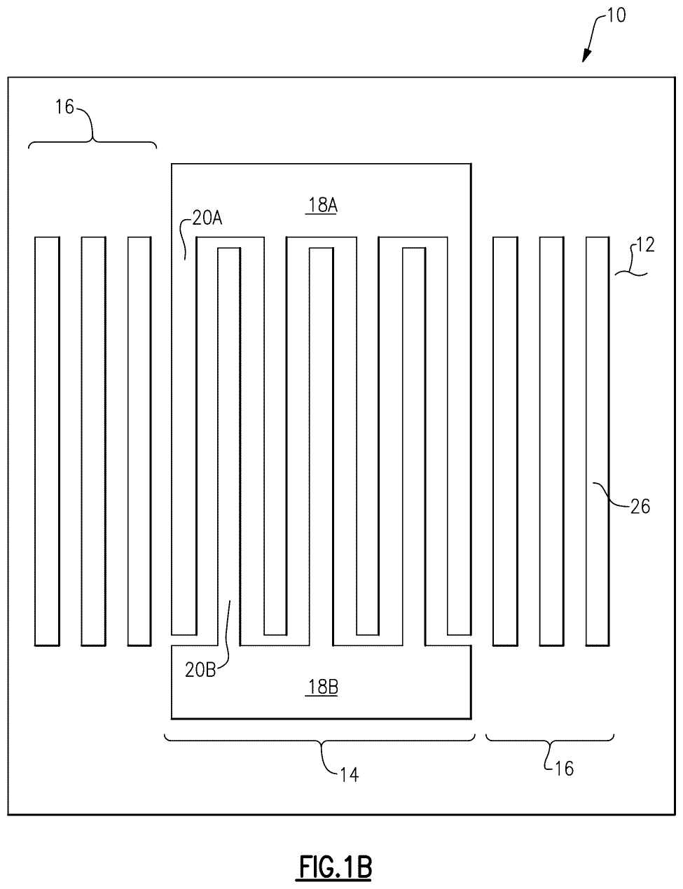

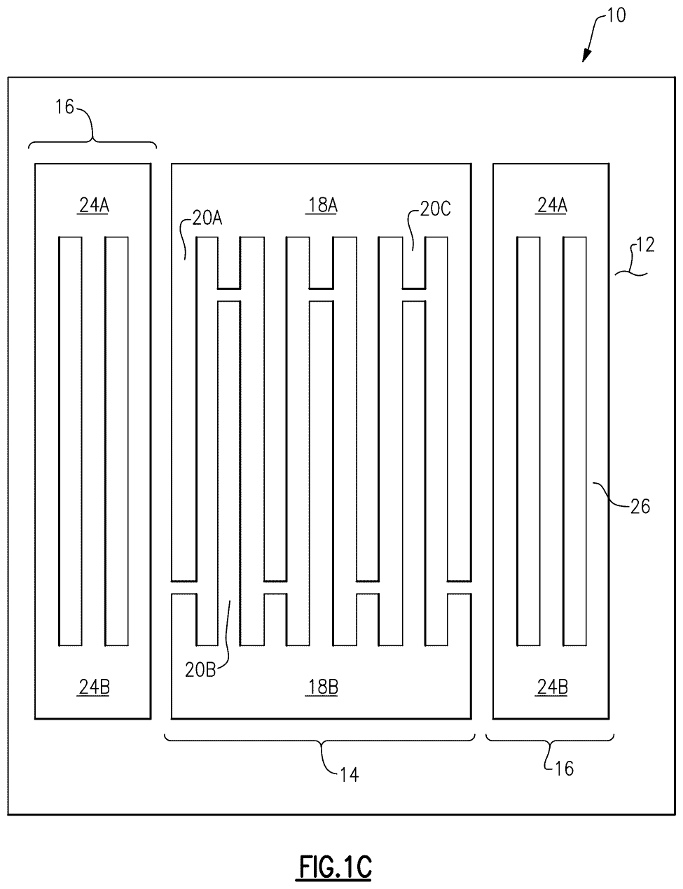

FIG. 1A is a plan view of a surface acoustic wave (SAW) resonator 10 such as might be used in a SAW filter, duplexer, balun, etc.

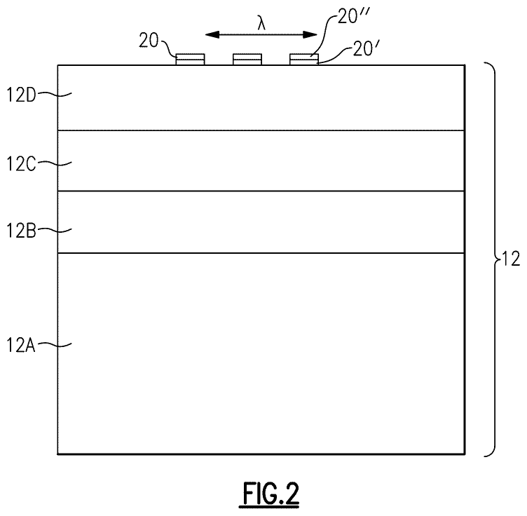

Acoustic wave resonator 10 is formed on a substrate 12 including a piezoelectric material layer, for example, a lithium tantalate (LiTaO₃) or lithium niobate (LiNbO₃) material layer. In some embodiments, as described with reference to FIG. 2 below, the substrate 12 may be a multilayer piezoelectric substrate (MPS). The acoustic wave resonator 10 includes Interdigital Transducer (IDT) electrodes 14 and reflector electrodes 16. In use, the IDT electrodes 14 excite a main acoustic wave having a wavelength λ along a surface of the substrate 12. The reflector electrodes 16 sandwich the IDT electrodes 14 and reflect the main acoustic wave back and forth through the IDT electrodes 14. The main acoustic wave of the device travels perpendicular to the lengthwise direction of the IDT electrodes.

The IDT electrodes 14 include a first bus bar electrode 18A and a second bus bar electrode 18B facing the first bus bar electrode 18A. The IDT electrodes 14 further include first IDT electrode fingers 20A extending from the first bus bar electrode 18A toward the second bus bar electrode 18B, and second IDT electrode fingers 20B extending from the second bus bar electrode 18B toward the first bus bar electrode 18A.

The reflector electrodes 16 (also referred to as reflector gratings or simply reflectors) each include a first reflector bus bar electrode 24A and a second reflector bus bar electrode 24B and reflector electrode fingers 26 extending between and electrically coupling the first bus bar electrode 24A and the second bus bar electrode 24B.

In other embodiments disclosed herein, as illustrated in FIG. 1B, the reflector bus bar electrodes 24A, 24B may be omitted and the reflector electrode fingers 26 may be electrically unconnected. Further, as illustrated in FIG. 1C, acoustic wave resonators as disclosed herein may include dummy electrode fingers 20C that are aligned with respective IDT electrode fingers 20A, 20B. Each dummy electrode finger 20C extends from the opposite bus bar electrode 18A, 18B than the respective IDT electrode finger 20A, 20B with which it is aligned.

It should be appreciated that the acoustic wave resonators 10 illustrated in FIGS. 1A-1C, as well as the other circuit elements illustrated in other figures presented herein, are illustrated in a highly simplified form. The relative dimensions of the different features are not shown to scale. Further, typical acoustic wave resonators would commonly include a far greater number of IDT electrode fingers and reflector electrode fingers than illustrated. Typical acoustic wave resonators or filter elements may also include multiple IDT electrodes sandwiched between the reflector electrodes.

FIG. 2 illustrates a cross-section of the substrate 12 and electrodes 20 that may be utilized in surface acoustic wave devices, for example, as illustrated in any of FIGS. 1A-1C above. The electrodes 20 of FIG. 2 may be any of the IDT electrodes fingers 20A, 20B, the dummy electrodes 20C, or the reflector electrode fingers 26 of a surface acoustic wave device, for example, as illustrated in any of FIGS. 1A-1C above. The electrodes 20 will, however, be referred to herein as IDT electrodes 20. The IDT electrodes 20 may be multilayer electrodes including a lower layer 20′ of a first metal and an upper layer 20″ of a second metal that is different from the first metal.

The substrate 12 is an MPS substrate including a support substrate 12A that may be formed of any of Si, quartz, sapphire, or any other suitable material to provide the substrate 12 with a desired amount of mechanical stability. A trap-rich layer 12B formed of, for example, polysilicon is disposed on top of the support substrate 12A and helps to reduce the generation of parasitic currents at the upper surface of the support substrate 12A. A layer 12C of a dielectric material, for example, a 600 nm thick layer of SiO₂ is disposed on the upper surface of the trap-rich layer 12B. Layer 12C may be referred to herein as a functional layer. A layer 12D of a piezoelectric material, for example, a 1,000 nm thick layer of lithium tantalate (LiTaO₃) or lithium niobate (LiNbO₃) is disposed on the upper surface of the layer 12C of dielectric material. The IDT electrodes 20 are disposed on the upper surface of the layer 12D of piezoelectric material. The piezoelectric material of layer 12D may exhibit a negative temperature coefficient of frequency. This may be compensated for by the positive temperature coefficient of frequency exhibited by the SiO₂ in the functional layer 12C.

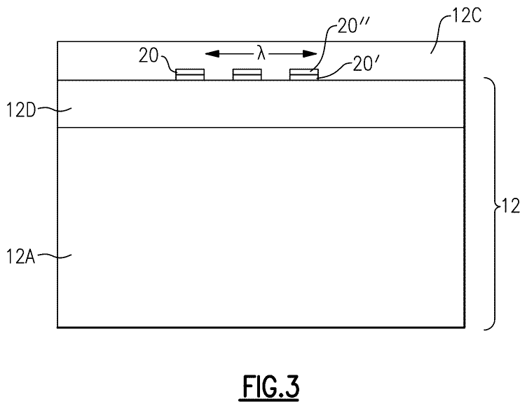

Another example of a substrate structure for a surface acoustic wave device, for example, as illustrated in any of FIGS. 1A-1C above is illustrated in FIG. 3. The substrate structure of FIG. 3 is similar to that of FIG. 2, however, the trap-rich layer 12B and functional layer 12C have been removed from beneath the layer 12D of piezoelectric material, although in some embodiments, the trap-rich layer may remain. The surface acoustic wave device structure of FIG. 3 also differs from that of FIG. 2 in that the functional layer 12C is disposed on top of the IDT electrodes 20 and the layer 12D of a piezoelectric material. In embodiments in which the functional layer 12C is formed of SiO₂ it may act as a temperature compensation layer for the acoustic wave device structure. A surface acoustic wave resonator having a structure such as shown in FIG. 3 may thus be referred to as a temperature compensated surface acoustic wave (TCSAW) resonator.

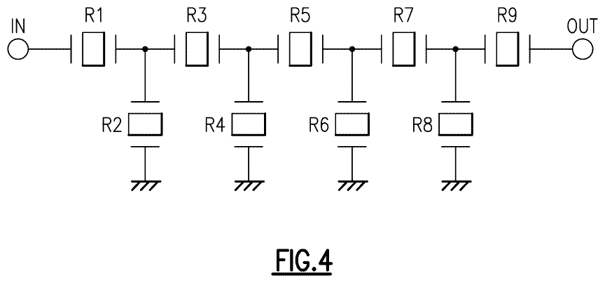

In some embodiments, multiple SAW resonators as disclosed herein may be combined into a filter, for example, an RF ladder filter as schematically illustrated in FIG. 4 and including a plurality of series resonators R1, R3, R5, R7, and R9, and a plurality of parallel or shunt resonators R2, R4, R6, and R8. As shown, the plurality of series resonators R1, R3, R5, R7, and R9 are connected in series between the input and the output of the RF ladder filter, and the plurality of parallel resonators R2, R4, R6, and R8 are respectively connected between series resonators and ground in a shunt configuration. Other filter structures and other circuit structures known in the art that may include SAW devices or resonators, for example, duplexers, baluns, etc., may also be formed including examples of SAW resonators as disclosed herein.

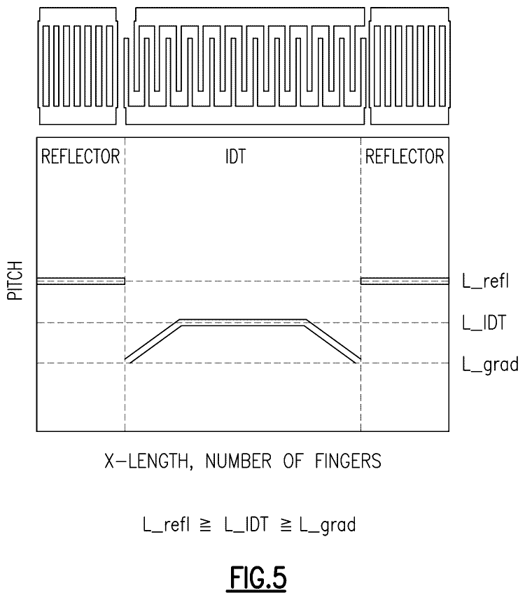

In some embodiments, the pitch of IDT electrode fingers 20A, 20B of a SAW resonator may vary across the width of the resonator in the direction of propagation of the main acoustic wave generated by the resonator. Additionally or alternatively, the pitch of the reflector electrode fingers 26 may be different from the pitch of the IDT electrode fingers 20A, 20B. One example of a SAW resonator with IDT electrode fingers that have different pitches and reflector electrode fingers with different pitches than the IDT electrode fingers is illustrated in plan view in FIG. 5. As illustrated, the IDT electrode fingers have a first pitch L_IDT that is constant throughout the center portion of the IDT electrodes with the pitch of the IDT electrode fingers decreasing to L_grad at the outside edges of the IDT electrodes. The pitch of the reflector electrode fingers is constant at a pitch L_refl that is greater than L_IDT and greater than L_grad. Utilization of different pitches for different IDT electrode fingers and different pitches for the reflector electrode fingers than for the IDT electrode fingers may help reduce the generation of spurious signals in the SAW resonator or help reduce the magnitude of spurious signals that reach the IDT electrodes from external sources as compared to a SAW resonator where all IDT electrode finger and reflector electrode finger pitches are the same.

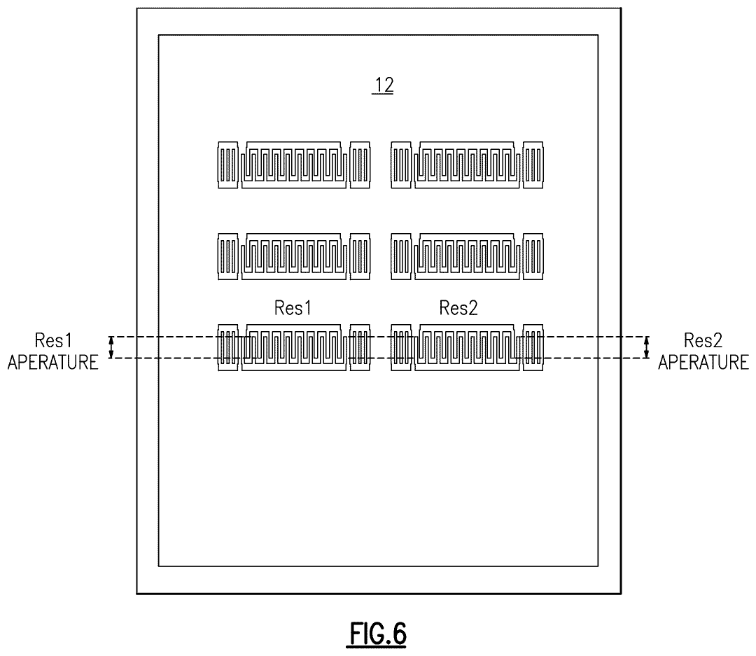

In the physical layout of the SAW resonators of a ladder filter such as illustrated in FIG. 4 (or another form of filter utilizing SAW resonators), two different resonators, for example, two different series resonators, two different parallel resonators, or a series resonator and a parallel resonator may be formed adjacent to one another with overlapping or at least partially overlapping apertures on the same substrate, for example, as illustrated in FIG. 6. The two resonators with the overlapping or at least partially overlapping apertures may have different resonant frequencies or in other embodiments, the same resonant frequencies. In such embodiments, SAW resonators having the pitch profile as illustrated in FIG. 5 may not be as effective as desired at suppressing spurious signals that may be generated by, for example, standing waves caused by reflection at end-faces of the substrate and/or other resonator patterns or by waves generated by different resonators.

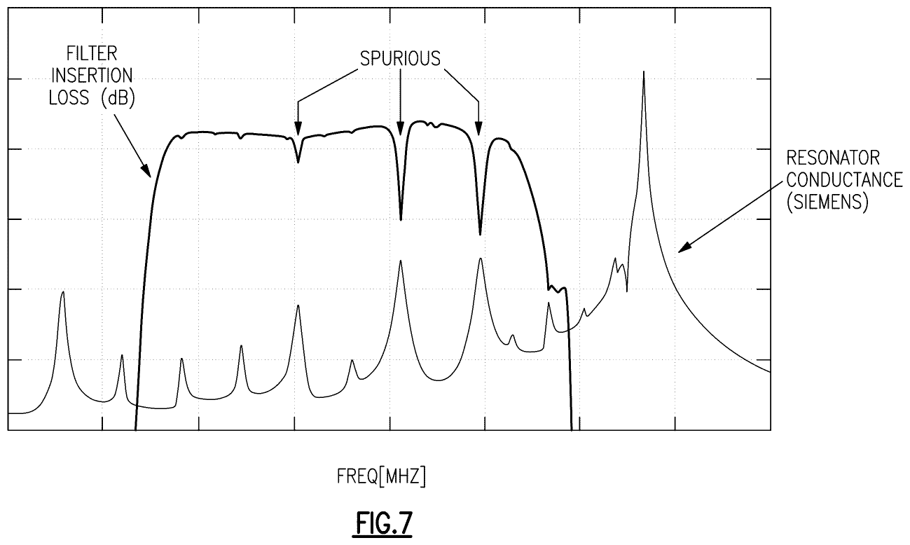

FIG. 7 illustrates the results of a simulation showing examples of spurious discontinuities in the insertion loss of a SAW filter with multiple resonators having the pitch profile illustrated in FIG. 5 and formed on the same substrate with some resonators having overlapping apertures as illustrated in FIG. 6.

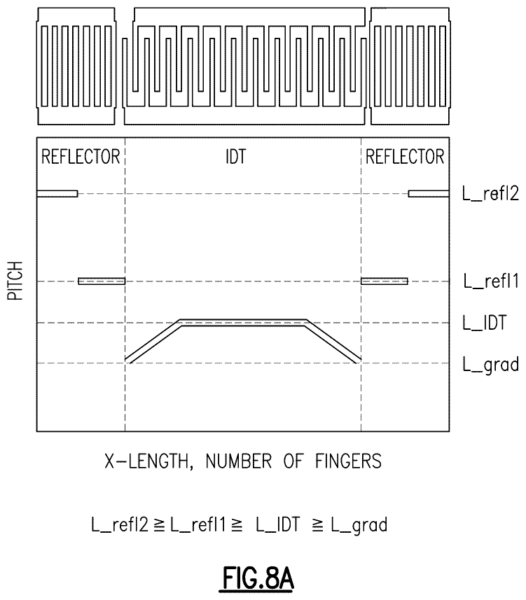

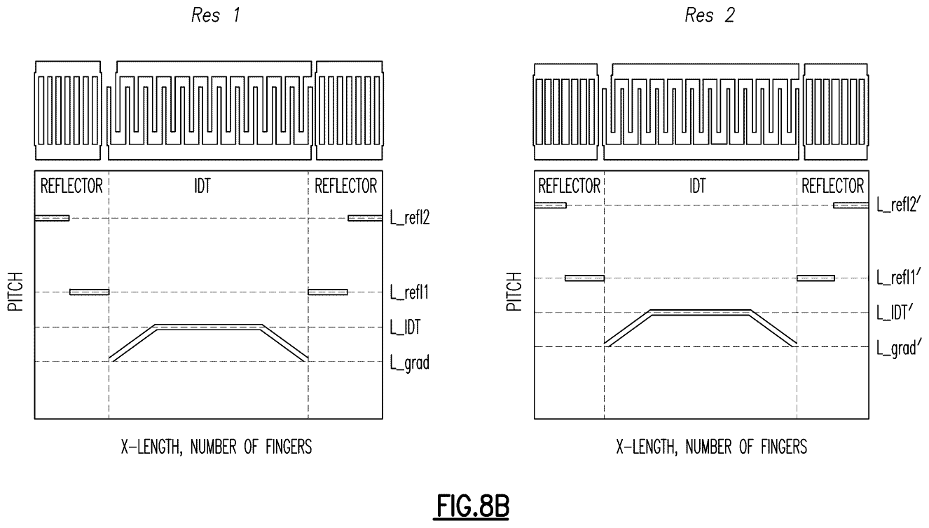

A modification to the resonator pitch profile may help suppress spurious signals in a SAW filter and reduce the magnitude of discontinuities in the filter insertion loss curve. One example of a SAW resonator with a modified pitch profile is illustrated in simplified plan view in FIG. 8A. In the SAW resonator of FIG. 8A, the IDT electrode fingers have a first pitch L_IDT throughout the center portion of the IDT electrodes with the pitch of the IDT electrode fingers decreasing to L_grad at the outside edges of the IDT electrodes. In some embodiments L_grad may be between 0.95 L_IDT and 1.0 L_IDT. The pitch of the reflector electrode fingers is set at a first pitch L_refl1 that is greater than L_IDT at inner sides of the reflector electrodes facing the IDT electrodes fingers. At a distance partially through the width of the reflector electrodes, for example, about halfway through the reflector electrode fingers, the reflector electrode finger pitch exhibits a step function and increases from L_refl1 to L_refl2 and remains at L_refl2 through the remainder of the reflector electrodes to the outside ends of the reflector electrodes. The first reflector electrode finger pitch L_refl1 may be set to maximize performance of the resonator and may be set at about 1.05*L_IDT. The second reflector electrode finger pitch L_refl2 may be tuned to have a stopband that suppresses external reflections or other spurious signals. In some embodiments L_refl2 may be set at about 1.10*L_IDT or at a pitch that covers the filter passband.

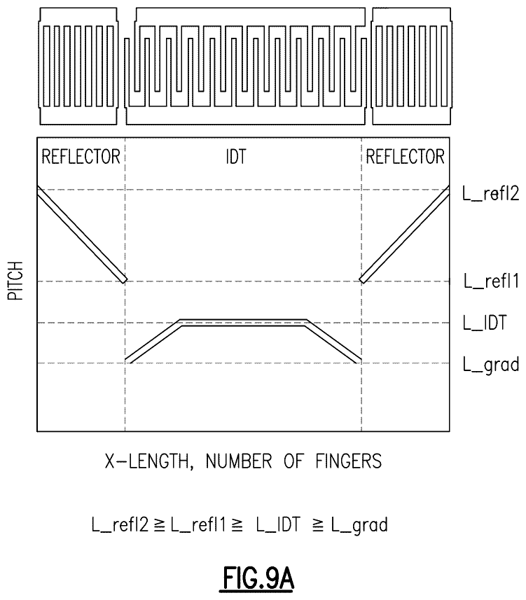

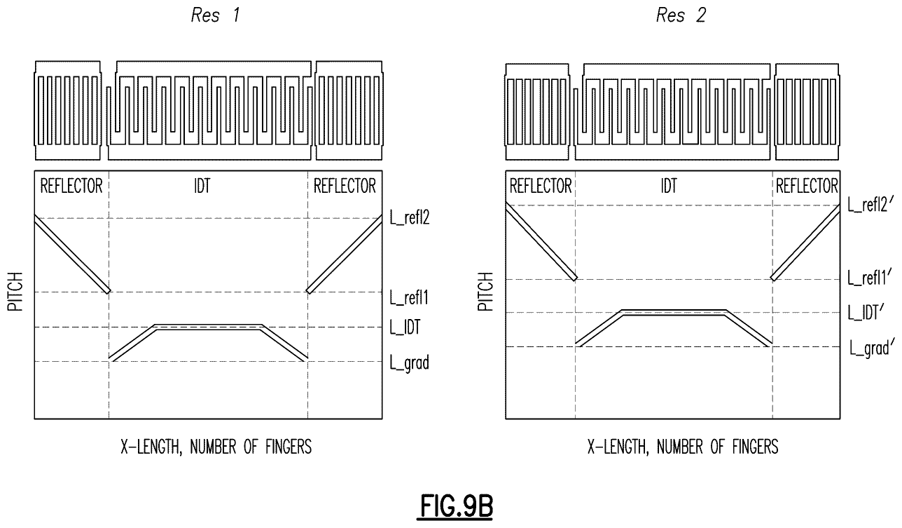

Another embodiment of a SAW resonator with a modified pitch profile is illustrated in simplified plan view in FIG. 9A. In the SAW resonator of FIG. 9A the IDT electrode fingers have a first pitch L_IDT throughout the center portion of the IDT electrodes with the pitch of the IDT electrode fingers decreasing to L_grad at the outside edges of the IDT electrodes in a similar manner as in the SAW resonator of FIG. 8A. The pitch of the reflector electrode fingers is set at a first pitch L_refl1 that is greater than L_IDT at inner sides of the reflector electrodes facing the IDT electrodes fingers and the smoothly increases to L_refl2 with distance toward the outside edges of the reflector electrodes. The increase in reflector electrode pitch with distance from the inner sides to the outer sides of the reflector electrodes may be monotonic or linearly increasing as illustrated in FIG. 9A.

It is to be appreciated that resonators with at least partially overlapping apertures, for example, the resonators labelled as Res1 and Res2 in FIG. 6 may have different IDT electrode finger and/or reflector electrode pitches. This is illustrated in FIGS. 8B and 9B where Res 2 is shown to have higher electrode finger and reflector electrode pitches L_grad′, L_IDT′, L_refl1′, and L_refl2′ than the corresponding electrode finger and reflector electrode pitches L_grad, L_IDT, L_refl1, and L_refl2 of Res1. In some embodiments, the same relationships between the electrode finger pitches of Res1 may hold for the relationships between the electrode finger pitches of Res2. For example, in some embodiments, L_refl1′ may be set at about 1.05*L_IDT′ and/or L_refl2′ may be set at about 1.10*L_IDT′.

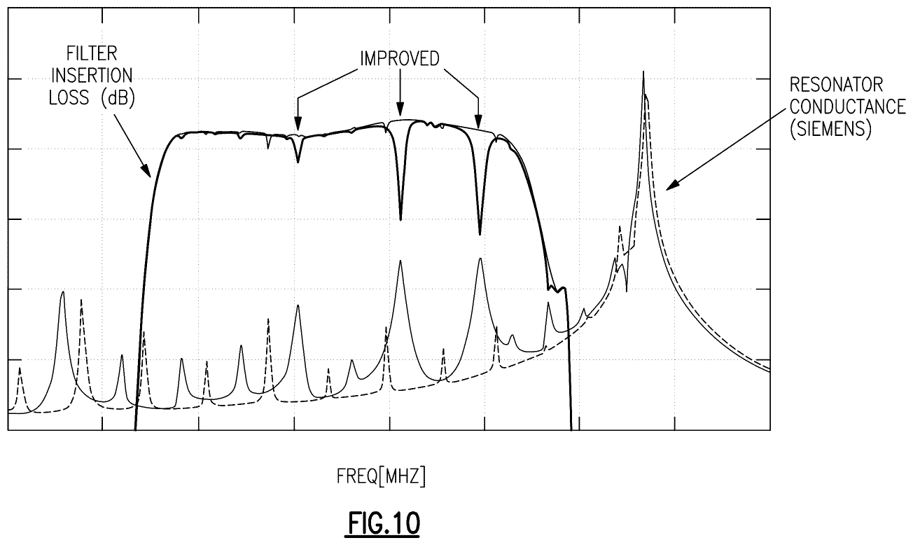

The simulation that produced the results shown in FIG. 7 was repeated with the resonators of the filter modelled as having the pitch profile shown in FIG. 8A rather than the pitch profile shown in FIG. 5. The results of this second simulation are shown in FIG. 10. As illustrated, the discontinuities in the filter insertion loss curve, as well as discontinuities in the resonator conductance were significantly reduced in magnitude when the resonators of the filter were modelled as having the pitch profile shown in FIG. 8A rather than the pitch profile shown in FIG. 5.

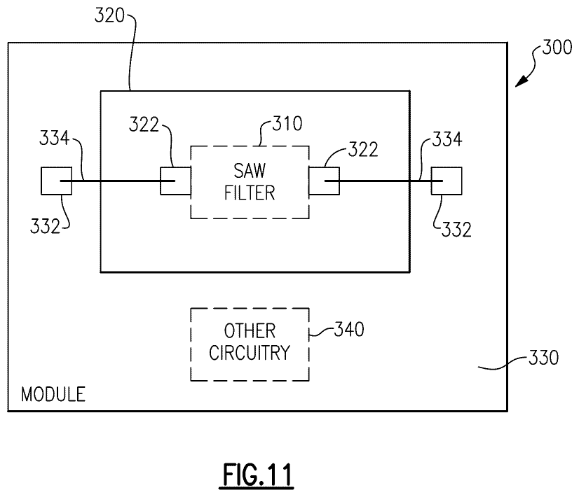

The acoustic wave resonators discussed herein can be implemented in a variety of packaged modules. Some example packaged modules will now be discussed in which any suitable principles and advantages of the packaged acoustic wave resonators discussed herein can be implemented. FIGS. 11, 12, and 13 are schematic block diagrams of illustrative packaged modules and devices according to certain embodiments.

As discussed above, embodiments of the surface acoustic wave elements can be configured as or used in filters, for example. In turn, a surface acoustic wave (SAW) filter using one or more surface acoustic wave elements may be incorporated into and packaged as a module that may ultimately be used in an electronic device, such as a wireless communications device, for example. FIG. 11 is a block diagram illustrating one example of a module 300 including a SAW filter 310. The SAW filter 310 may be implemented on one or more die(s) 320 including one or more connection pads 322. For example, the SAW filter 310 may include a connection pad 322 that corresponds to an input contact for the SAW filter and another connection pad 322 that corresponds to an output contact for the SAW filter. The packaged module 300 includes a packaging substrate 330 that is configured to receive a plurality of components, including the die 320. A plurality of connection pads 332 can be disposed on the packaging substrate 330, and the various connection pads 322 of the SAW filter die 320 can be connected to the connection pads 332 on the packaging substrate 330 via electrical connectors 334, which can be solder bumps or wirebonds, for example, to allow for passing of various signals to and from the SAW filter 310. The module 300 may optionally further include other circuitry die 340, for example, one or more additional filter(s), amplifiers, pre-filters, modulators, demodulators, down converters, and the like, as would be known to one of skill in the art of semiconductor fabrication in view of the disclosure herein. In some embodiments, the module 300 can also include one or more packaging structures to, for example, provide protection and facilitate easier handling of the module 300. Such a packaging structure can include an overmold formed over the packaging substrate 330 and dimensioned to substantially encapsulate the various circuits and components thereon.

Various examples and embodiments of the SAW filter 310 can be used in a wide variety of electronic devices. For example, the SAW filter 310 can be used in an antenna duplexer, which itself can be incorporated into a variety of electronic devices, such as RF front-end modules and communication devices.

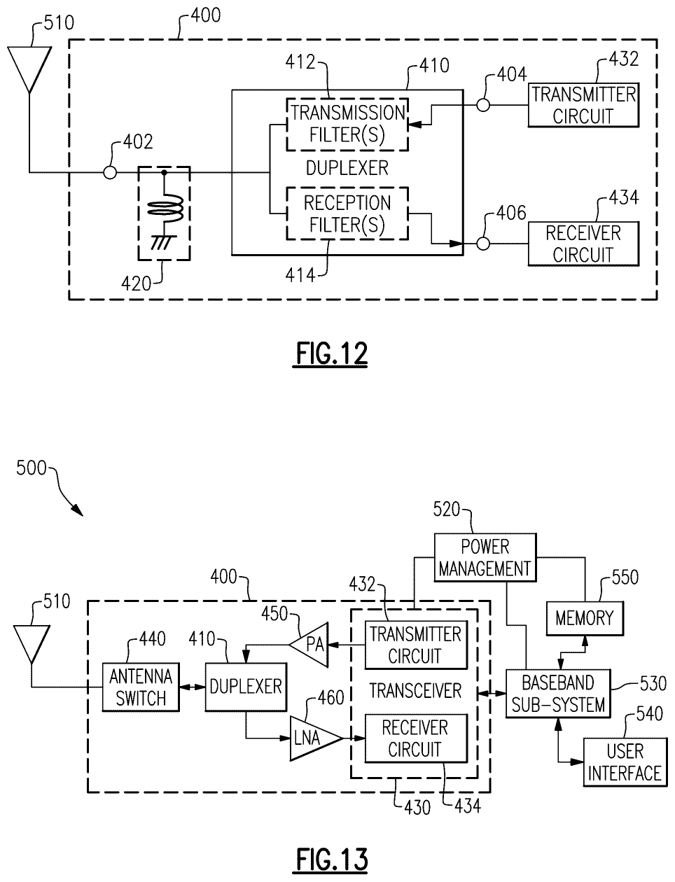

Referring to FIG. 12, there is illustrated a block diagram of one example of a front-end module 400, which may be used in an electronic device such as a wireless communications device (e.g., a mobile phone) for example. The front-end module 400 includes an antenna duplexer 410 having a common node 402, an input node 404, and an output node 406. An antenna 510 is connected to the common node 402.

The antenna duplexer 410 may include one or more transmission filters 412 connected between the input node 404 and the common node 402, and one or more reception filters 414 connected between the common node 402 and the output node 406. The passband(s) of the transmission filter(s) are different from the passband(s) of the reception filters. Examples of the SAW filter 310 can be used to form the transmission filter(s) 412 and/or the reception filter(s) 414. An inductor or other matching component 420 may be connected at the common node 402.

The front-end module 400 further includes a transmitter circuit 432 connected to the input node 404 of the duplexer 410 and a receiver circuit 434 connected to the output node 406 of the duplexer 410. The transmitter circuit 432 can generate signals for transmission via the antenna 510, and the receiver circuit 434 can receive and process signals received via the antenna 510. In some embodiments, the receiver and transmitter circuits are implemented as separate components, as shown in FIG. 12, however in other embodiments these components may be integrated into a common transceiver circuit or module. As will be appreciated by those skilled in the art, the front-end module 400 may include other components that are not illustrated in FIG. 12 including, but not limited to, switches, electromagnetic couplers, amplifiers, processors, and the like.

FIG. 13 is a block diagram of one example of a wireless device 500 including the antenna duplexer 410 shown in FIG. 12. The wireless device 500 can be a cellular phone, smart phone, tablet, modem, communication network or any other portable or non-portable device configured for voice or data communication. The wireless device 500 can receive and transmit signals from the antenna 510. The wireless device includes an embodiment of a front-end module 400 similar to that discussed above with reference to FIG. 12. The front-end module 400 includes the duplexer 410, as discussed above. In the example shown in FIG. 13 the front-end module 400 further includes an antenna switch 440, which can be configured to switch between different frequency bands or modes, such as transmit and receive modes, for example. In the example illustrated in FIG. 13, the antenna switch 440 is positioned between the duplexer 410 and the antenna 510; however, in other examples the duplexer 410 can be positioned between the antenna switch 440 and the antenna 510. In other examples the antenna switch 440 and the duplexer 410 can be integrated into a single component.

The front-end module 400 includes a transceiver 430 that is configured to generate signals for transmission or to process received signals. The transceiver 430 can include the transmitter circuit 432, which can be connected to the input node 404 of the duplexer 410, and the receiver circuit 434, which can be connected to the output node 406 of the duplexer 410, as shown in the example of FIG. 12.

Signals generated for transmission by the transmitter circuit 432 are received by a power amplifier (PA) module 450, which amplifies the generated signals from the transceiver 430. The power amplifier module 450 can include one or more power amplifiers. The power amplifier module 450 can be used to amplify a wide variety of RF or other frequency-band transmission signals. For example, the power amplifier module 450 can receive an enable signal that can be used to pulse the output of the power amplifier to aid in transmitting a wireless local area network (WLAN) signal or any other suitable pulsed signal. The power amplifier module 450 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 450 and associated components including switches and the like can be fabricated on gallium arsenide (GaAs) substrates using, for example, high-electron mobility transistors (pHEMT) or insulated-gate bipolar transistors (BiFET), or on a Silicon substrate using complementary metal-oxide semiconductor (CMOS) field effect transistors.

Still referring to FIG. 13, the front-end module 400 may further include a low noise amplifier module 460, which amplifies received signals from the antenna 510 and provides the amplified signals to the receiver circuit 434 of the transceiver 430.

The wireless device 500 of FIG. 13 further includes a power management sub-system 520 that is connected to the transceiver 430 and manages the power for the operation of the wireless device 500. The power management system 520 can also control the operation of a baseband sub-system 530 and various other components of the wireless device 500. The power management system 520 can include, or can be connected to, a battery (not shown) that supplies power for the various components of the wireless device 500. The power management system 520 can further include one or more processors or controllers that can control the transmission of signals, for example. In one embodiment, the baseband sub-system 530 is connected to a user interface 540 to facilitate various input and output of voice and/or data provided to and received from the user. The baseband sub-system 530 can also be connected to memory 550 that is configured to store data and/or instructions to facilitate the operation of the wireless device, and/or to provide storage of information for the user. Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 5 GHZ, such as in a range from about 600 MHz to 2.7 GHZ.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to”. The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A die comprising a plurality of surface acoustic wave resonators, at least one of the plurality of surface acoustic wave resonators having an aperture that at least partially overlaps an aperture of at least one other of the plurality of surface acoustic wave resonators, the at least one of the plurality of surface acoustic wave resonators including interdigital transducer electrodes with interdigital transducer electrode fingers having a first average pitch and reflector electrodes with reflector electrode fingers having at least two different pitches, each of the at least two different pitches being greater than the first average pitch.

2. The die of claim 1 wherein the interdigital transducer electrode fingers of the at least one of the plurality of surface acoustic wave resonators have a first constant pitch throughout a center portion of the interdigital transducer electrodes and a second average pitch proximate outer sides of the interdigital transducer electrodes on opposite sides of the center portion.

3. The die of claim 2 wherein the pitches of the interdigital transducer electrode fingers decrease monotonically with distance from outer edges of the center portion to the outer sides of the interdigital transducer electrodes.

4. The die of claim 2 wherein the reflector electrode fingers have a second constant pitch throughout inner portions of the reflector electrodes and a third constant pitch throughout outer portions of the reflector electrodes.

5. The die of claim 4 wherein the third constant pitch is greater than the second constant pitch.

6. The die of claim 5 wherein the second constant pitch is about 1.05 times the first constant pitch.

7. The die of claim 5 wherein the third constant pitch is about 1.1 times the first constant pitch.

8. The die of claim 2 wherein the pitches of the reflector electrode fingers increase with distance from inner sides of the reflector electrodes to outer sides of the reflector electrodes.

9. The die claim 8 wherein the pitches of the reflector electrode fingers increase monotonically with distance from the inner sides of the reflector electrodes to the outer sides of the reflector electrodes.

10. The die of claim 8 wherein the pitch of the reflector electrode fingers is about 1.05 times the first constant pitch at the inner sides of the reflector electrodes.

11. The die of claim 8 wherein the pitch of the reflector electrode fingers is about 1.1 times the first constant pitch at the outer sides of the reflector electrodes.

12. The die of claim 1 wherein each of the plurality of surface acoustic wave resonators include interdigital transducer electrodes with interdigital transducer electrode fingers having a first average pitch and reflector electrodes with reflector electrode fingers having at least two different pitches, each of the at least two different pitches being greater than the first average pitch.

13. The die of claim 1 wherein the at least one of the plurality of surface acoustic wave resonators and the at least one other of the plurality of surface acoustic wave resonators have partially overlapping apertures.

14. The die of claim 13 wherein the at least one of the plurality of surface acoustic wave resonators and the at least one other of the plurality of surface acoustic wave resonators have interdigital transducer electrode fingers with different average pitches.

15. The die of claim 13 wherein the at least one of the plurality of surface acoustic wave resonators and the at least one other of the plurality of surface acoustic wave resonators have reflector electrode fingers with different average pitches.

16. The die of claim 1 wherein the plurality of surface acoustic wave resonators form a radio frequency filter.

17. The die of claim 16 wherein the plurality of surface acoustic wave resonators form a radio frequency ladder filter.

18. An electronics module comprising the radio frequency filter of claim 17.

19. An electronic device including the electronics module of claim 18.

20. A radio frequency filter comprising a plurality of surface acoustic wave resonators disposed on a substrate, at least one of the plurality of surface acoustic wave resonators having an aperture that at least partially overlaps an aperture of at least one other of the plurality of surface acoustic wave resonators, the at least one of the plurality of surface acoustic wave resonators including interdigital transducer electrodes with interdigital transducer electrode fingers having a first average pitch and reflector electrodes with reflector electrode fingers having at least two different pitches, each of the at least two different pitches being greater than the first average pitch.
